(19) United States
(12) Patent Application Publication
(10) Pub. No.: US 2003/0218873 A1
(43) Pub. Date: Nov. 27, 2003

(54) Structure for fastening a component

(75) Inventors: Marko Eromaki, Tampere (FI); Esa Maatta, Viiala (FI)

Correspondence Address: WARE FRESSOLA VAN DER SLUYS &, ADOLPHSON, LLP, BRADFORD GREEN BUILDING 5, 755 MAIN STREET, P O BOX 224, MONROE, CT, 06468, US

(73) Assignee: Nokia Corporation

(21) Appl. No.: 10/444,777

(22) Filed: May 23, 2003

(30) Foreign Application Priority Data
May 27, 2002 (FI) 20020992

(51) Int. Cl. H05K 9/00

(52) U.S. Cl. 361/816

(57) ABSTRACT

A method and a fastening structure for fastening a component (3) in an electronic device, the fastening structure comprising at least a frame (1) and flexible fastening means (11) arranged therein. The fastening means (11), which are placed substantially against the surface of the component (3) to be fitted in the frame (1), is arranged to fasten the component (3) and to suppress electromagnetic radiation.

### CROSS-REFERENCE TO RELATED APPLICATIONS

This application claims priority under 35 USC §119 to Finnish Patent Application No. 20020992 filed on May 27, 2002.

### FIELD OF THE INVENTION

The invention relates to a method for fastening a component in an electronic device according to the preamble of the appended claim 1. The invention also relates to a device according to the preamble of the appended claim 13. In addition, the invention relates to a fastening structure according to the preamble of the appended claim 27.

### BACKGROUND OF THE INVENTION

In their operation, various electrical devices and components induce spurious electromagnetic signals, which may be of either the radiating or conductive type. Radiating spurious signals may be narrow-band interference caused by e.g. radio transmitters, or wideband interference caused by almost any electrical devices. Spurious signals conducted along structures, such as conductors, are also caused by almost all electrical devices, but in most cases their effect is insignificant when compared with radiating spurious signals. The magnitude of electromagnetic interference caused by a device or a component depends, for example, on the voltage, current and frequency used in the device or component.

On the other hand, the operation of devices and components may be disturbed by the electromagnetic field effective on them. The interference resistance of a device and a component, that is, the quantity of interference that may be present in its environment without its operation being disturbed, is influenced, for example, by the voltages, currents and frequencies to be used in the device or component, and particularly in its control.

Electromagnetic interference is attenuated as the distance is increased, but in devices in which a compact size is aimed at, for example in mobile stations, other methods must be used to reduce the effect of electromagnetic radiation. A typical method is to place the elements inducing strong electromagnetic interference apart from the elements sensitive to interference, as well as to encapsulate such elements. The encapsulation to reduce electromagnetic radiation is often implemented by a box-like structure formed by metal to accommodate the element to be insulated. The implementation of the structure, for example the size and placing of the openings, is used to affect its capacity to suppress radiation at different frequency ranges.

In mobile station, there are both narrow-band electromagnetic interference caused by the transmitter part and elements sensitive to said interference. A particular feature in mobile station applications is the limited space available, and therefore the distances between the interfering and disturbed components are short, wherein problems may be caused by even weak electromagnetic interference. As there is primarily very limited space available, also the shielding and attenuating structures should be implemented by saving space, and the shielding and attenuating structures used are typically various encapsulating solutions surrounding the components, wherein the fasteners of the bottom part connected to a circuit board are provided with a cover part. The part to be insulated, typically a part such as an integrated circuit which is sensitive to interference caused by a transmitter, is placed in the space between the bottom part and the cover part.

U.S. Pat. No. 4,890,199 discloses an encapsulating method, in which a separate cover part is connected to separate fasteners forming the bottom part placed around the component to be insulated. The component to be insulated, fixed to a circuit board, is thus placed in the space limited by the bottom part and the cover part. According to the publication, the fasteners of the bottom part consist of spring-like structures, which exert their compressive forces in substantially opposite directions, wherein the cover part fitted at its edges between the spring-like means is fixed to the bottom part. Thus, the structure composed of separate elements forms a box-like shielding structure to suppress electromagnetic interference.

U.S. Pat. No. 6,181,573, in turn, discloses an encapsulating method, in which a separate cover part is fitted inside a bottom part placed around the component to be insulated. Also in this solution, the component to be insulated, fixed to a circuit board, is placed in the space limited by the bottom part and the cover part. The fasteners of the bottom part according to the publication are spring-like lips, which exert the compressive force substantially on the inside of the frame. Thus, the cover part fitted inside the bottom part is strongly connected to the bottom part, and the formed structure acts as a substantially solid shielding structure to suppress electromagnetic interference.

In the solutions presented above, the shielding structure is formed around the component connected to a circuit board by a separate bottom part and a separate cover part in such a way that the box-like shielding structure, consisting of the parts and being separate from the component, surrounds the component in substantially all directions. In the shielding of such components which require a mechanical or optical connection outside the shield structure, such as camera modules, the complicated implementation of a mechanical lead-in duct or optical connection must be fitted in the shield structure, typically the cover part of the shield structure. Furthermore, because of the structures of the actual cover part and the fasteners in the cover part, the overall outer dimensions of the shielded structure become considerably greater than those of the unshielded component, wherein the requirement for installation space will naturally also be greater.

### SUMMARY OF THE INVENTION

The primary aim of the present invention is to present a method, in which the shielding of a component against electromagnetic radiation is implemented without a separate cover part.

To attain this purpose, the method according to the invention is primarily characterized in what will be presented in the characterizing part of the independent claim 1.

The invention further relates to a device, which is primarily characterized in what will be presented in the characterizing part of the independent claim 13.

The fastening structure according to the invention, in turn, is primarily characterized in what will be presented in the characterizing part of the independent claim 27.

The other dependent claims will present some preferred embodiments of the invention.

The main idea of the invention is to implement the fastening structure of the component in such a way that said fastening structure acts as a shielding structure to suppress electromagnetic interference and, in particular, as a structure suppressing electromagnetic radiation.

The shielding fastening structure is preferably a frame-like structure enveloping the component to be shielded and having one substantially open side. On one side, the structure is provided with coupling means to connect the fastening structure to the circuit board, and said coupling means are preferably placed on the side opposite to the open side of the fastening structure, which side is preferably placed against the circuit board. Hereinbelow, the shielding and fastening structure according to the invention will be called a frame, and the bottom of the frame will refer to that side of the structure, which is provided with the coupling means.

The component to be shielded from electromagnetic radiation by the structure according to the invention can be any suitable electronic component, such as for example a camera module to be used in a mobile station. The component to be shielded is placed inside the frame, which frame can be placed in a desired environment, for example on a circuit board. The component is fitted in the frame preferably with a connecting adapter placed between the component and the bottom of the frame.

The edges surrounding the bottom of the frame are preferably holders formed of flexible strips, each strip being tightly placed, at least at one point, against the surface of the component fitted in the frame. The flexible holders keep the component, fitted in the frame, and the possible connecting adapter in position, and press the component against the connecting surface, simultaneously preventing the movement of the component and the connecting adapter off the bottom. Thus, other fastening means than the frame will not be needed to fix the component and the adapter and to keep them in position.

Preferably, the frame is made of metal, such as a spring-like thin sheet (for example, tin bronze, phosphorus bronze), wherein the penetration of electromagnetic radiation is effectively suppressed. By fitting the frame with such a component whose structure prevents the penetration of electromagnetic radiation through the upper surface (the surface opposite to the joining surface), the structure of the component and the frame in connection with the component surface becomes an effective shield against electromagnetic interference.

The electromagnetic shield structure implemented by the method of the invention will not require a separate cover part to suppress radiation. It is thus possible to fit the component in a smaller space than in solutions with a cover, and the whole enveloping structure can thus be made smaller. The elimination of a separate cover part is also a desirable feature in the shielding of such components which require a mechanical or optical connection outside the shield structure, such as for example an optical connection required by a camera module to an object to be imaged.

Furthermore, in an advantageous embodiment of the invention, it is possible to install and remove the component very fast, which is particularly useful in the assembly and in the maintenance. It is also possible to implement the shielding by using fewer separate parts for shielding and fastening the component than in solutions of prior art. In a very advantageous embodiment, the component to be installed is fitted with a separate joining part, or adapter, in the frame, wherein the first contacts of the adapter correspond to the contacts of the circuit board, and the second contacts correspond to the contacts of the component. Thus, when the component is replaced with a component of another type, it will only be necessary to replace the adapter with another adapter of a suitable type, the frame remaining the same.

### DESCRIPTION OF THE DRAWINGS

In the following, the invention will be described in more detail with reference to the principle drawings, in which

FIG. 1 shows the frame structure according to an embodiment of the invention,

FIG. 2 shows an adapter suitable for the frame of FIG. 1,

FIG. 3 shows a frame suitable for the adapter, seen from above,

FIG. 4 shows the assembly of FIG. 3 seen from the bottom direction, when it is fitted with the adapter of FIG. 2,

FIG. 5 shows the frame structure and a camera module fitted in it, and

FIG. 6 shows a detail in the assembly of FIG. 5.

### DETAILED DESCRIPTION OF THE INVENTION

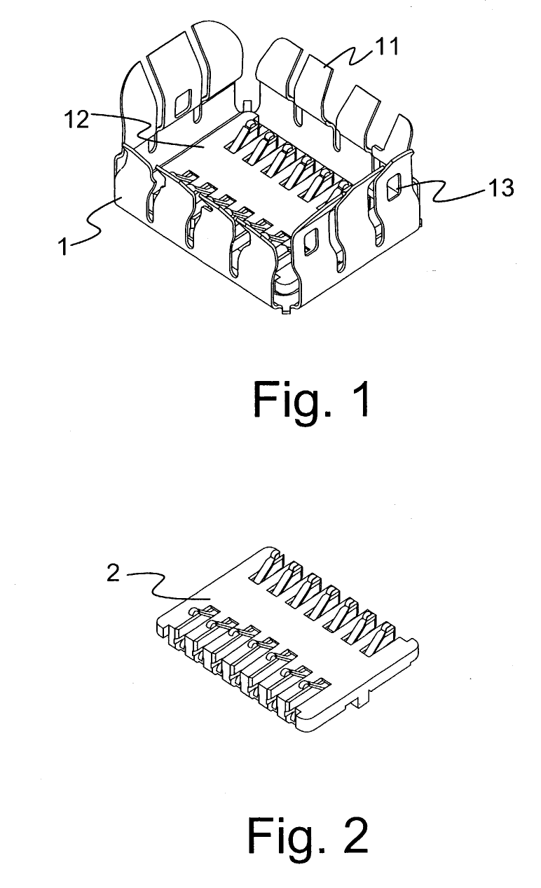

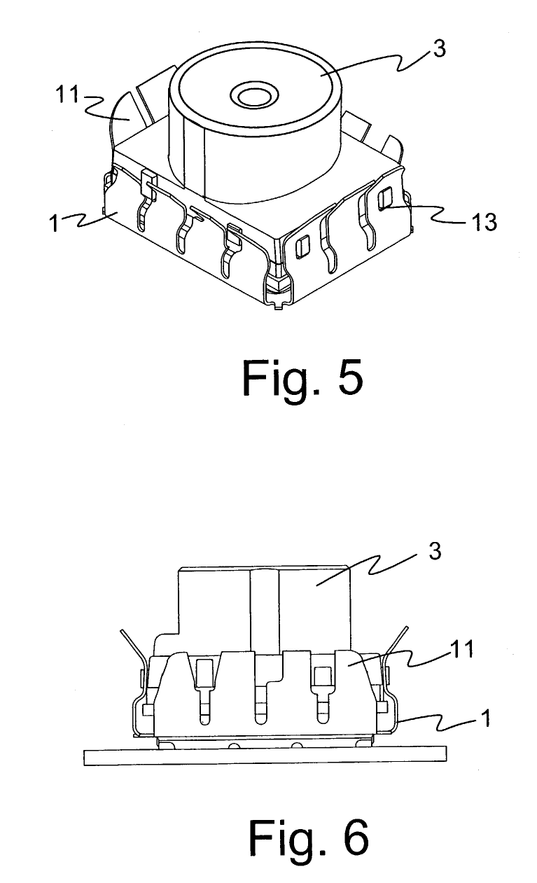

In this example embodiment, the structure according to the invention comprises a frame 1 as shown in FIG. 1, provided with an integrated or replaceable plug part 2 as shown in FIG. 2. As shown in FIG. 5, the frame 1 can be fitted with a component 3, wherein the strips 11 of the frame are placed against the component, as shown in FIG. 6, holding it fast and simultaneously forming a shield against electromagnetic radiation. Preferably, the frame 1 is used as an equipotential bonding element between the component 3 and the rest of the structure, such as the circuit board.

The frame 1 is preferably a structure encasing the component 3, with its one side substantially open to fit the component in the frame. Here-inbelow, the side opposite to the open side of the frame will be called the bottom 12. In the embodiment of FIG. 1, the bottom 12 of the frame 1 is surrounded by edges, which preferably consist of flexible strips 11 close to each other, each strip having preferably the form of a clasp-like tongue 11. The distances between the tongues 11 are dimensioned so that electromagnetic radiation at the frequency to be suppressed will not penetrate the structure. Advantageously, the size of the slot between the tongues 11 is 1 to 3 mm, preferably less than 2 mm. The edges and tongues 11 of the frame 1 preferably act as fasteners for the component 3, and they will be called fasteners 11 here-inbelow. Each fastener 11 is placed, at least at one point, tightly against the surface of the component 3 fitted in the frame. Differing from the example, the fasteners 11 can be formed by a substantially integrated means on each side of the frame 1, instead of separate strip-like means. The uniform structure is used to achieve substantially the same effect as with the separate fasteners 11, but in the case of some small components 3, it is, for reasons of manufacturing technique and economy, advantageous to use on each side a uniform fastener 11 extending on the side.

One side of the frame is provided with coupling means to connect the structure to the circuit board, and said coupling means are preferably placed on the bottom 12 of the frame, this side being preferably placed against the circuit board. The coupling means may be integrated in the structure of the frame 1, but preferably the coupling means are placed in a separate structure in relation to the frame, such as e.g. an adapter 2 according to FIG. 2. The first side of the adapter 2 is provided with contacts corresponding to the contacts of the circuit board, and the second side is provided with contacts corresponding to the contacts of the component 3. A connection is formed between the contacts on the first side and the contacts on the other side of the adapter 2, as required by the application, for example to match the order of pins in the component and in the circuit board.

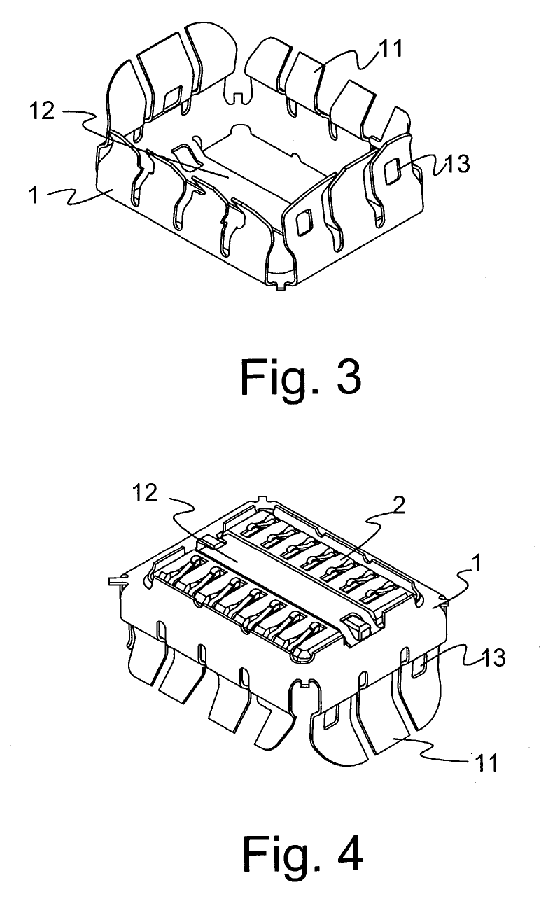

The adapter 2 is arranged in connection with the circuit board as shown in FIGS. 3 and 4, by means of openings formed in the bottom 12 of the frame 1 and preferably being placed against the circuit board. The adapter 2 is typically specific to the component, and when replacing the component 3 with another component with contacts differing from those of the previous component, it is normally necessary to change the adapter as well. In practice, the use of the adapter 2 has e.g. the advantage that it is possible to easily and quickly fit components of different types in the same frame 1, the contact solutions being different from each other but their operating principles and outer dimensions being, however, substantially the same. An example to be mentioned is connectors with 14 and 20 contacts in different types of camera modules, of which the 20-contact module can often be utilized by means of 14 contacts. The adapter 2 makes it possible to replace and update the components 3 with new types in a flexible way without a need to change the whole frame structure 1.

The connector frame 1 according to the invention can be provided with a component 3, such as the camera module shown in the example FIG. 5, but the component 3 to be shielded from electromagnetic radiation may be any electronic component, which fits in the frame. Depending on the application, the component 3 can be fitted in the frame 1 either with or without the adapter part 2.

In an advantageous embodiment, the frame 1 is connected to the equipotential bonding structure of the surrounding structure, such as the ground plane. Thus, the frame 1 acts as the conductive equipotential bonding element between the component 3, particularly the shell of the component, and the rest of the structure, such as the circuit board or the other structures of the device.

In an advantageous embodiment, the component 3 to be fitted in the frame 1 is formed in such a way that its structure substantially prevents the penetration of electromagnetic radiation through the surface opposite to the contact surface, referred to as the upper surface. The upper surface can be, for example, made of a suitable material, or the upper surface can be coated with a material substantially impermeable to radiation. It is also possible to arrange a separate part to cover said upper surface of the component 3. When the component 3 is fitted in the frame 1, the parts sensitive to interference being placed close to the connector surface, the structure of the frame will substantially shield the component from weak interference even without a shield on the side of the upper surface, as long as the interfering radiation comes in a direction substantially different from the upper surface.

In view of preventing the propagation of electromagnetic radiation, it is advantageous to arrange the joint between the surface of the component 3 shielding from electromagnetic radiation, preferably the upper surface, and the fasteners 11 of the frame 1, to be continuous. Preferably, the connection is implemented in the above-described manner by means of fasteners 11 substantially close to each other, formed of flexible strips, each fastener being tightly placed, at least at one point, against the component 3 fitted in the frame. The largest diameter of the slot between the contact points in the adjacent fasteners 11 and on the surface of the component 3 is preferably less than 3 mm.

When the component 3 is fitted in the frame 1, the fasteners 11 according to the invention yield to the component, becoming wider from the inner part of the frame outwards, thanks to their spring-like structure. A similar yielding of the fasteners 11 also occurs when the component 3 is removed from the frame 1. The spring-like fasteners 11 keep the component 3 to be fitted in the frame 1 substantially in its place, and substantially compress the bottom 12 towards the component and towards the possible connector adapter 2 which is placed between the component and the bottom as shown in FIG. 6, simultaneously preventing the movement of the component and the connector adapter away from the bottom. Thus, the fasteners 11 provide a reliable connection between the fastener and the component 3 fitted in the frame 1, as well as between said component and the contact surfaces.

According to the invention, no other separate fastening means than the frame 1 will be needed to fasten the component 3 and the adapter 2, and to keep them in their place. If necessary, the frame 1 can be provided with one or more stopper means 13, as shown for example in FIG. 1, to secure that the component 3 remains in its position. The stopper means 13 can have the shape of a hole-like opening, as in the example, but the stopper means can also be formed in another way, for example as a fold or a bulge formed in the frame. The component 3 engages with the stopper means 13 at a structure, such as a protrusion shown in the example, the protrusion fitting in the hole acting as the stopper means. The component 3 is released from the stopper 13, for example, by bending the fastener 11 away from the component. By a corresponding principle, it is possible to provide the frame 1 with guiding structures to secure that the component 3 is installed in the correct position.

By combining the modes and structures presented in connection with the different embodiments of the invention presented above, it is possible to provide various embodiments of the invention in accordance with the spirit of the invention. Therefore, the above-presented examples must not be interpreted as restrictive to the invention, but the embodiments of the invention can be freely varied within the scope of the inventive features presented in the claims here-inbelow.

1. A method for fastening a component in an electronic device, the method comprising at least a frame and flexible fastening means arranged in it, wherein the component is fitted in said frame in such a way that the surface of the component is in contact with the fastening means arranged for fastening the component and for suppressing electromagnetic radiation.

2. The method according to claim 1, wherein a shield structure is made of said frame and component, against electromagnetic radiation.

3. The method according to claim 1, wherein the frame is made a structure as tight as possible, to prevent the penetration of electromagnetic radiation.

4. The method according to claim 1, wherein the contact points between adjacent fastening means and the component are formed at a distance of less than 3 mm from each other.

5. The method according to claim 1, wherein the fastening means is arranged to yield when the component is being placed in and out of the frame.

6. The method according to claim 1, wherein the frame also comprises at least a connector means, by which the component is connected to the current circuit to be formed.

7. The method according to claim 6, wherein the connector part is arranged between the component and the bottom part of the frame.

8. The method according to claim 6, wherein the connector part comprises first contact means which are fitted in connection with the contact means of the component, as well as second contact means which are fitted in connection with the current circuit to be formed.

9. The method according to claim 6, wherein the connector part is detachable.

10. The method according to claim 1, wherein the frame is fitted with a component which is an electronic component and which is a functional element in the current circuit to be formed.

11. The method according to claim 1, wherein the frame is fitted with a component, which is a camera module.

12. The method according to claim 1, wherein the frame is used to connect the component and the structure surrounding the frame to the same potential.

13. An electronic device comprising a fastening structure for fastening a component, the fastening structure comprising at least a frame and flexible fastening means arranged therein, wherein
the fastening means are arranged to be placed against the surface of the component to be fitted in the frame, and
said fastening means are arranged for fastening the component and for suppressing electromagnetic radiation.

14. The device according to claim 13, wherein the device is a mobile station.

15. The device according to claim 13, wherein said fastening structure and the component are arranged to form a shielding structure against electromagnetic radiation.

16. The device according to claim 13, wherein the fastening structure forms a structure which is as tight as possible, to prevent the penetration of electromagnetic radiation.

17. The device according to claim 13, wherein the distance between the contact points formed by adjacent fastening means and the component is less than 3 mm.

18. The device according to claim 13, wherein the fastening means is a flexible strip arranged to yield when the component is placed in and out of the frame.

19. The device according to claim 13, wherein the fastening structure also comprises at least a connector part for connecting the component with the current circuit to be formed.

20. The device according to claim 19, wherein the connector part is arranged to be fitted between the component and the bottom part of the frame.

21. The device according to claim 19, wherein the connector part comprises first contact means which can be fitted in connection with the contact means of the component, as well as second contact means which can be fitted in connection with the current circuit to be formed.

22. The device according to claim 19, wherein the connector part is arranged to be detachable.

23. The device according to claim 13, wherein the component to be fitted in the fastening structure is an electronic component, which is a functional part of the current circuit to be formed.

24. The device according to claim 13, wherein the component to be fitted in the fastening structure is a camera module.

25. The device according to claim 13, wherein the fastening structure is made of a metal thin sheet.

26. The device according to claim 13, wherein the fastening structure connects the component and the structure surrounding the fastening structure to the same potential.

27. A fastening structure for a component, comprising at least a frame and flexible fastening means arranged therein, wherein the fastening means, which are placed against the surface of the component to be fitted in the frame, are arranged to fasten the component and to suppress electromagnetic radiation.

28. The fastening structure according to claim 27, wherein said fastening structure and the component are arranged to form a shielding structure against electromagnetic radiation.

29. The fastening structure according to claim 27, wherein the fastening structure forms a structure which is as tight as possible, to prevent the penetration of electromagnetic radiation.

30. The fastening structure according to claim 27, wherein the distance between the contact points formed by adjacent fastening means and the component is less than 3 mm.

31. The fastening structure according to claim 27, wherein the fastening means is a flexible strip arranged to yield when the component is placed in and out of the frame.

32. The fastening structure according to claim 27, wherein the fastening structure also comprises at least a connector part for connecting the component with the current circuit to be formed.

33. The fastening structure according to claim 32, wherein the connector part is arranged to be fitted between the component and the bottom part of the frame.

34. The fastening structure according to claim 32, wherein the connector part comprises first contact means which can be fitted in connection with the contact means of the component, as well as second contact means which can be fitted in connection with the current circuit to be formed.

35. The fastening structure according to claim 32, wherein the connector part is arranged to be detachable.

36. The fastening structure according to claim 27, wherein the component to be fitted in the fastening structure is an electronic component, which is a functional part of the current circuit to be formed.

37. The fastening structure according to claim 27, wherein the component to be fitted in the fastening structure is a camera module.

38. The fastening structure according to claim 27, wherein the fastening structure is made of a metal thin sheet.

39. The fastening structure according to claim 27, wherein said fastening structure connects the component and the structure surrounding the fastening structure to the same potential.
